(19) United States
(12) Patent Application Publication
(10) Pub. No.: US 2016/0086968 A1
(43) Pub. Date: Mar. 24, 2016

(54) SEMICONDUCTOR DEVICE

(71) Applicant: MACRONIX International Co., Ltd., Hsinchu (TW)

(72) Inventors: Zu-Sing Yang, Hsinchu (TW); Cheng-Yi Lung, Hsinchu (TW)

(21) Appl. No.: 14/490,137

(22) Filed: Sep. 18, 2014

(51) Int. Cl. H01L 27/115

(52) U.S. Cl. CPC H01L 27/11575; H01L 27/11582; H01L 27/11568

(57) ABSTRACT

A semiconductor device is provided. The semiconductor device includes a substrate, a plurality of stack structures, and a plurality of support layers. The stack structures are disposed on the substrate, and a trench is formed between adjacent two stack structures. Each of the stack structures includes a plurality of conductor layers and a plurality of dielectric layers. The dielectric layers and the conductor layers are disposed alternately. The support layers are disposed in the stack structures respectively.

### BACKGROUND OF THE INVENTION

1. Field of the Invention

The invention relates to a semiconductor device.

2. Description of Related Art

As semiconductor devices are integrated, in order to achieve high density and high performance, fabrication of semiconductor devices has evolved into stacking upward in the vertical direction, such that the wafer area can be used more efficiently.

Generally, when forming a semiconductor structure that has a higher aspect ratio, e.g. a high aspect ratio trench, the challenge is that the structures on two sides of the trench may bend or collapse. This phenomenon causes difficulty in the follow-up fabrication processes and has adverse effects on the electrical test of the semiconductor device. Hence, how to prevent the semiconductor structures of higher aspect ratio from bending or collapse is an important issue that needs to be overcome in this field.

### SUMMARY OF THE INVENTION

The invention provides a semiconductor device for improving an anti-collapse property of a stack structure and reducing occurrence of a Z-axis interference.

The invention provides a semiconductor device that includes a substrate, a plurality of stack structures, and a plurality of support layers. The stack structures are disposed on the substrate. A trench is formed between adjacent two stack structures. Each of the stack structures includes a plurality of conductor layers and a plurality of dielectric layers. The dielectric layers and the conductor layers are disposed alternately. The support layers are disposed in the stack structures respectively.

In an embodiment of the invention, a Young's modulus of the support layers is greater than a Young's modulus of the conductor layers.

In an embodiment of the invention, a band gap of the support layers is greater than a band gap of the conductor layers.

In an embodiment of the invention, a material of the support layers includes silicon carbide, silicon nitride, or a combination thereof.

In an embodiment of the invention, each of the stack structures includes two or more of the support layers.

In an embodiment of the invention, the support layers are respectively disposed on an upper surface or a lower surface of one of the conductor layers.

In an embodiment of the invention, an aspect ratio of the trench is in a range of 10-180.

In an embodiment of the invention, the semiconductor device further includes a plurality of conductive columns disposed in the trenches respectively.

In an embodiment of the invention, the semiconductor device further includes a charge storage layer disposed between the stack structures and the conductive columns.

The invention provides a semiconductor device that includes a substrate, a plurality of stack structures, and a plurality of support layers. The stack structures are disposed on the substrate. A trench is formed between adjacent two stack structures. Each of the stack structures includes a plurality of composite layers. The support layers are respectively disposed above or under the composite layers.

In an embodiment of the invention, each of the composite layers includes a conductor layer and a dielectric layer.

In an embodiment of the invention, a Young's modulus of the support layers is greater than a Young's modulus of the conductor layers.

In an embodiment of the invention, a band gap of the support layers is greater than a band gap of the conductor layers.

In an embodiment of the invention, a material of the support layers includes silicon carbide, silicon nitride, or a combination thereof.

In an embodiment of the invention, an aspect ratio of the trench is in a range of 10-180.

The invention provides a semiconductor device that includes a substrate, a plurality of first stack structures, a plurality of second stack structures, and a plurality of support layers. The first stack structures are disposed on the substrate. A trench is formed between adjacent two first stack structures. The second stack structures are respectively disposed on the first stack structures. The support layers are disposed between the first stack structures and the second stack structures respectively.

In an embodiment of the invention, a Young's modulus of the support layers is greater than a Young's modulus of a first conductor layer in the first stack structures and greater than a Young's modulus of a second conductor layer in the second stack structures.

In an embodiment of the invention, each of the first stack structures includes a plurality of first composite layers and each of the second stack structures includes a plurality of second composite layers. A plurality of material layers of the first composite layers and a plurality of material layers of the second composite layers have different compositions, structures, or arrangements.

In an embodiment of the invention, a material of the support layers includes silicon carbide, silicon nitride, or a combination thereof.

In an embodiment of the invention, an aspect ratio of the trench is in a range of 10-180.

Based on the above, in the semiconductor device provided by the invention, the stack structures are formed with the support layers therein, so as to prevent bending or collapse of the stack structures. Particularly, for the semiconductor device that has high aspect ratio trenches between the stack structures, the overall Young's modulus of the semiconductor device is improved by disposing the support layers having greater Young's modulus than the conductor layers in the stack structures, thereby preventing occurrence of bending or collapse. In addition, when the support layers have a greater band gap than the conductor layers, occurrence of the Z-axis interference between adjacent conductor layers is also reduced.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic cross-sectional view illustrating a semiconductor device according to an embodiment of the invention.

FIG. 2A to FIG. 2H are schematic cross-sectional views illustrating a fabricating method of a semiconductor device according to an embodiment of the invention.

### DESCRIPTION OF THE EMBODIMENTS

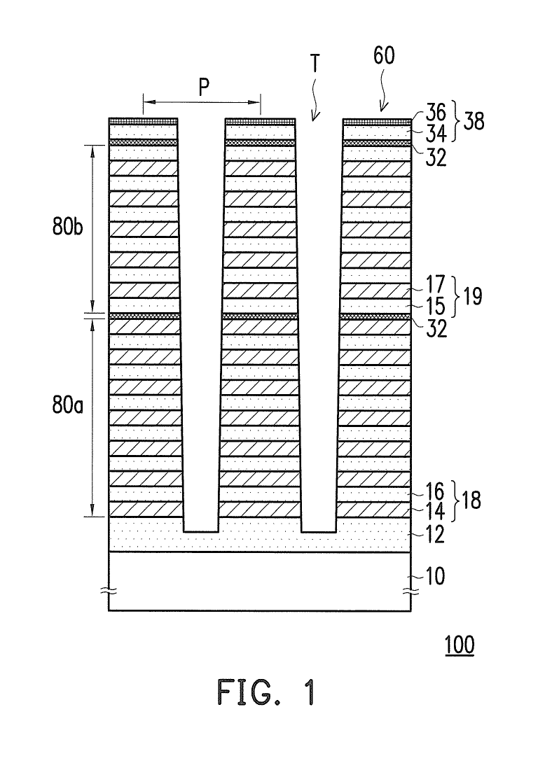

FIG. 1 is a schematic cross-sectional view illustrating a semiconductor device according to an embodiment of the invention.

With reference to FIG. 1, a semiconductor device 100 includes a substrate 10, a plurality of stack structures 60, and a plurality of support layers 32. The substrate 10 may include a semiconductor material, an insulator material, a conductor material, or any combination of the foregoing materials. The material of the substrate 10 is a material composed of at least one selected from a group consisting of Si, Ge, SiGe, GaP, GaAs, SiC, SiGeC, InAs, and InP, or any physical structure suitable for a fabricating process of the invention, for example. The substrate 10 includes a single-layer structure or a multi-layer structure. In addition, a silicon on insulator (SOI) substrate may be used as the substrate 10. The substrate 10 is silicon or silicon germanium, for example.

The stack structures 60 are disposed on the substrate 10. A trench T is formed between adjacent two stack structures 60. The trench T may be formed with any length, width, or shape. The trench T may be a wide trench or a narrow trench. In an embodiment, the width of the trench T is in a range of 5 nm to 30 nm, for example. A depth of the trench T is in a range of 500 nm to 5,000 nm, for example. In other words, the trench T has a higher aspect ratio. In an embodiment, the aspect ratio of the trench T is in a range of 10-180, for example. A cross section of the trench T may be in any shape, such as V shape, U shape, rhombus, or a combination of the foregoing, for example. However, it should be noted that the invention is not limited thereto. In an embodiment, a pitch P between adjacent two stack structures 60 is in a range of 10 nm to 86 nm, for example.

With reference to FIG. 1 again, each of the stack structures 60 includes a partially patterned dielectric layer 12, a plurality of conductor layers 14, and a plurality of dielectric layers 16. The patterned dielectric layer 12 includes oxide, nitride, nitrogen oxide, or a low dielectric constant material having a dielectric constant smaller than 4. In an embodiment, the patterned dielectric layer 12 is a bottom oxide layer (BOX), for example. A thickness of the dielectric layer 12 is in a range of 10 nm to 900 nm, for example.

The conductor layers 14 and the dielectric layers 16 are disposed on the patterned dielectric layer 12. The conductor layers 14 and the dielectric layers 16 are disposed alternately. In an embodiment, the conductor layer 14 is disposed on the patterned dielectric layer 12, and the dielectric layer 16 is disposed on the conductor layer 14. The conductor layers 14 and the dielectric layers 16 are alternately stacked upward on the substrate 10, so as to form a plurality of the stack structures 60. The dielectric layer 16 and the dielectric layer 12 may be formed of the same or different materials. The material of the dielectric layer 16 includes oxide, nitride, nitrogen oxide, or a low dielectric constant material having a dielectric constant smaller than 4. A thickness of the dielectric layer 16 is in a range of 100 nm to 500 nm, for example. A material of the conductor layer 14 includes an undoped semiconductor or a doped semiconductor, such as polysilicon or doped polysilicon. A thickness of the conductor layer 14 is in a range of 100 nm to 500 nm, for example. In this embodiment, the stack structure 60 is formed by alternately disposing a polysilicon layer and an oxide layer.

Further, referring to FIG. 1 again, each of the stack structures 60 may selectively include a hard mask layer 38 thereon. The hard mask layer 38 may include a single layer or multiple layers. In an embodiment, the hard mask layer 38 includes a first hard mask layer 34 and a second hard mask layer 36. The first hard mask layer 34 includes an oxide layer, and a material thereof is silicon oxide or other suitable materials, for example. A thickness of the first hard mask layer 34 is in a range of 10 nm to 200 nm, for example. The second hard mask layer 36 includes a nitride layer, and a material thereof is silicon nitride or other suitable materials, for example. A thickness of the second hard mask layer 36 is in a range of 10 nm to 200 nm, for example. It is worth mentioning that the second hard mask layer 36 may be formed of a material, such as silicon nitride, having a Young's modulus greater than a Young's modulus of the conductor layer 14. Therefore, when the second hard mask layer 36 having greater Young's modulus than the conductor layer 14 (e.g. polysilicon) is disposed as a topmost layer of the stack structure 60, an overall Young's modulus of the stack structure 60 is further increased to enhance an anti-collapse property of the structure.

The support layers 32 can be disposed at random locations in the stack structure 60 respectively. In an embodiment, the support layer 32 is disposed at a height where each stack structure 60 is most likely to collapse, so as to improve a structural strength of the stack structure 60. Moreover, the support layers 32 are respectively disposed on an upper surface or a lower surface of any conductor layer 14, for example. In another embodiment, the support layers 32 are respectively disposed on the upper surface or the lower surface of the conductor layer 14 in a range where each stack structure 60 is most likely to collapse. The support layers 32 may be formed of any material having a Young's modulus greater than the Young's modulus of the conductor layer 14. The support layers 32 may also be formed of any material having a band gap greater than a band gap of the conductor layer 14. The material of the support layers 32 is silicon carbide, silicon nitride, or a combination thereof, for example. A thickness of the support layer 32 is in a range of 5 nm to 100 nm, for example.

In another embodiment, each of the stack structures 60 is formed by stacking a plurality of composite layers 18 upward on the substrate 10. Each of the composite layers 18 may be composed of one conductor layer 14 and one dielectric layer 16. Each of the composite layers 18 may also be composed of one conductor layer 14 and multiple dielectric layers 16. Each of the composite layers 18 may also be composed of multiple conductor layers 14 and one dielectric layer 16. In an embodiment, each of the composite layers 18 is a multi-layer structure including two or more layers of a polysilicon layer and an oxide layer. However, the composite layer 18 of the invention is not limited to the above. The support layers 32 are respectively disposed above or under any composite layer 18 in each stack structure 60, for example. More specifically, the support layers 32 are respectively disposed on the upper surface or the lower surface of the conductor layer 14 in any composite layer 18, for example.

It should be noted that material structure deformation is related to the Young's modulus, and the structure becomes more difficult to deform as the Young's modulus of the material increases. Accordingly, it is known that when the support layer 32 having greater Young's modulus than the conductor layer 14 is disposed in the stack structure 60, the overall Young's modulus of the stack structure 60 is improved such that the stack structure 60 does not deform easily. Moreover, in an embodiment of the invention, each stack structure 60 may include two or more support layers 32 therein, such that the overall Young's modulus of the stack structure 60 is further increased to prevent bending or collapse.

On the other hand, it is known that a Z-axis interference may easily occur when the conductor layers 14 (e.g. polysilicon layer) are close to each other. That is, electrons in the conductor layers 14 (e.g. polysilicon layer) located close to each other may interfere with each other during operation of the device and cause false signals. In the semiconductor device 100 of the invention, when the support layer 32 having a greater band gap than the conductor layer 14 is disposed in the stack structure 60, for example, the support layer 32 is disposed on the upper surface of an n^{th} conductor layer 14. Because the band gap of the support layer 32 is greater than the band gap of the conductor layer 14, it is difficult for the electrons in the n^{th} conductor layer 14 to transit to an n+1^{th} conductor layer 14. Thus, occurrence of the Z-axis interference between adjacent conductor layers 14 is reduced. However, the invention is not limited thereto. In another embodiment, the support layer 32 may be disposed on the lower surface of the n^{th} conductor layer 14.

With reference to FIG. 1, in yet another embodiment of the invention, the semiconductor device 100 includes the substrate 10, a plurality of first stack structures 80a, a plurality of second stack structures 80b, and a plurality of support layers 32. The first stack structures 80a are disposed on the substrate 10, and the trench T is formed between adjacent two first stack structures 80a. The trench T has a higher aspect ratio. The aspect ratio of the trench T is in a range of 10-180, for example. Each of the first stack structures 80a includes a plurality of composite layers 18, and the composite layer 18 includes the conductor layer 14 and the dielectric layer 16, for example.

The second stack structures 80b are respectively disposed on the first stack structures 80a. Each of the second stack structures 80b includes a plurality of composite layers 19, and the composite layer 19 includes a dielectric layer 15 and a conductor layer 17, for example. Each composite layer 19 and each composite layer 18 may have the same or different materials, compositions, structures, or arrangements. The support layers 32 are respectively disposed between the first stack structures 80a and the second stack structures 80b, or the support layers 32 may be disposed on the second stack structures 80b. The material of the support layers 32 includes silicon carbide, silicon nitride, or a combination thereof, for example. In an embodiment, the Young's modulus of the support layer 32 is greater than the Young's modulus of the conductor layer 14 in the first stack structure 80a and greater than a Young's modulus of the conductor layer 17 in the second stack structure 80b.

In the above embodiments, composite material layers in the stack structure or the composite layer are arranged in an order. However, the stack structure and the composite layer of the invention are not limited thereto, and the composite material layers may also be arranged in a random order. In other words, the invention covers the scope where the support layers are disposed in the stack structures having a high aspect ratio trench therebetween.

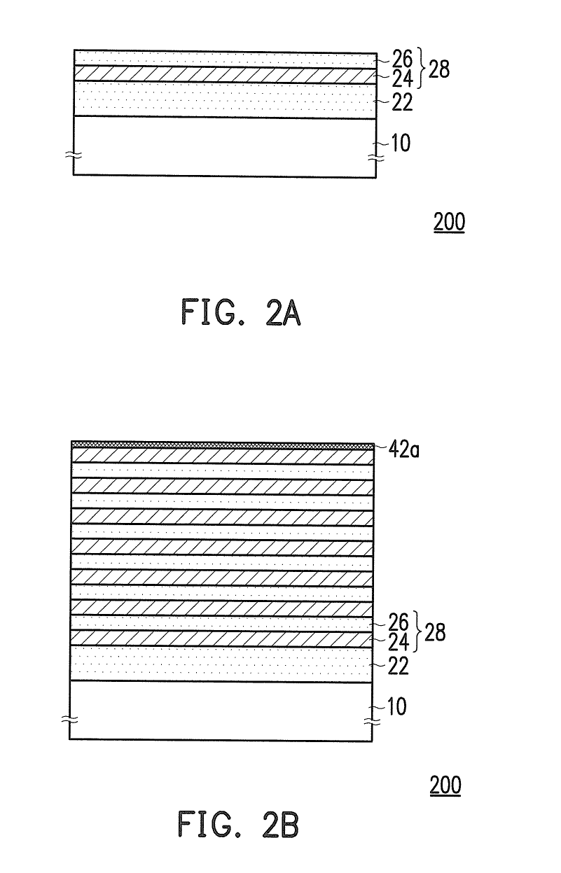

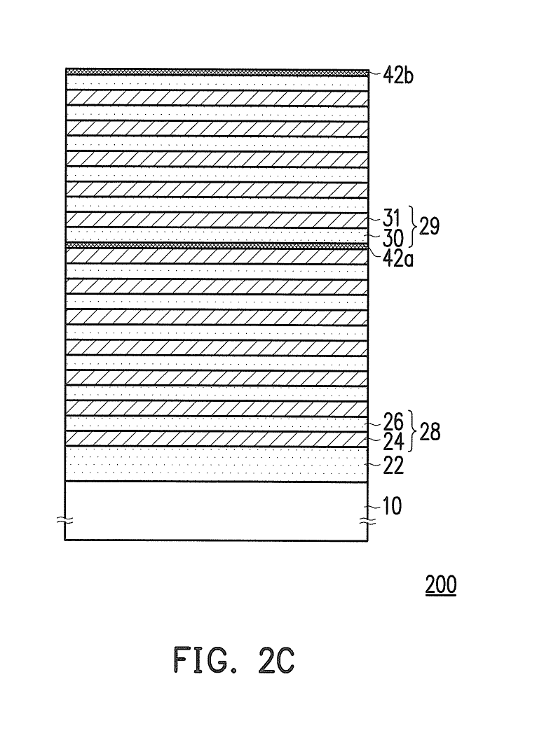

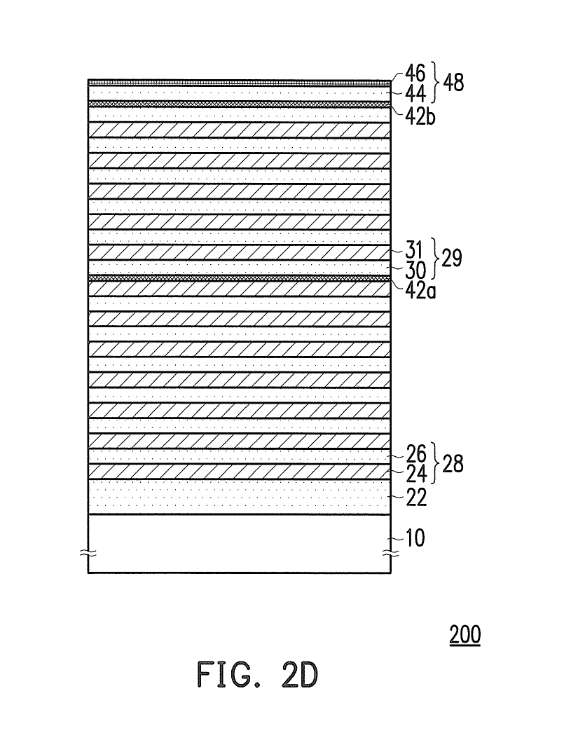

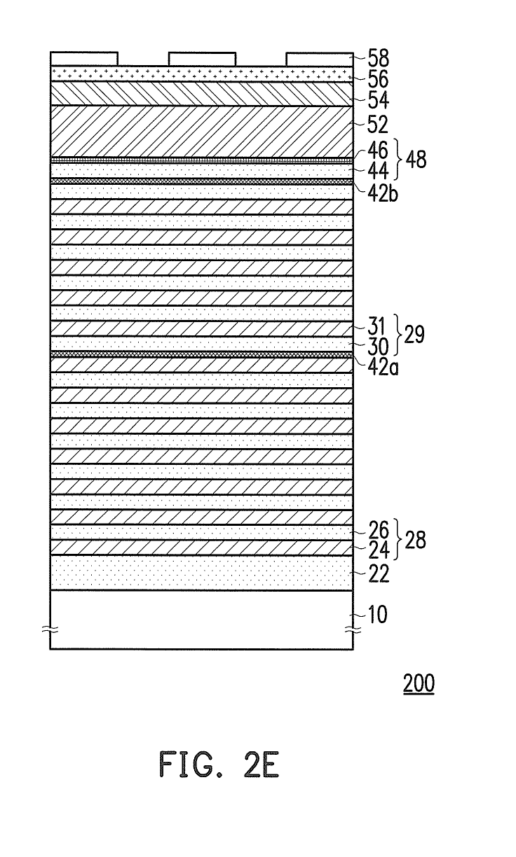

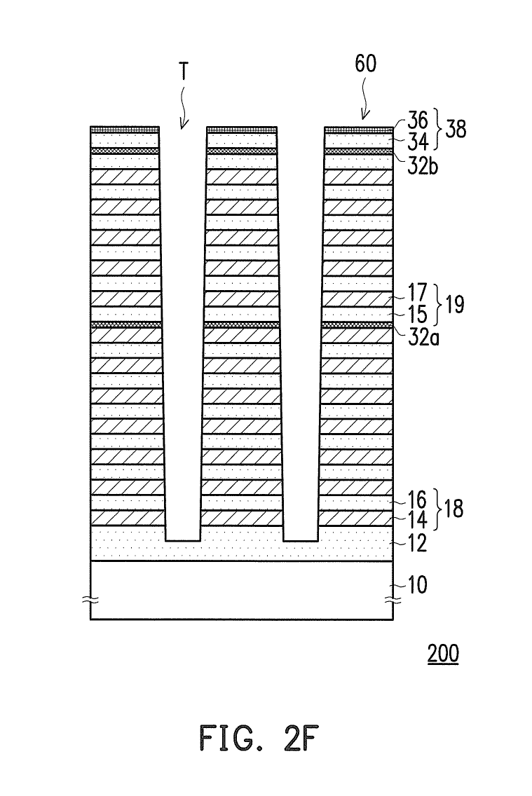

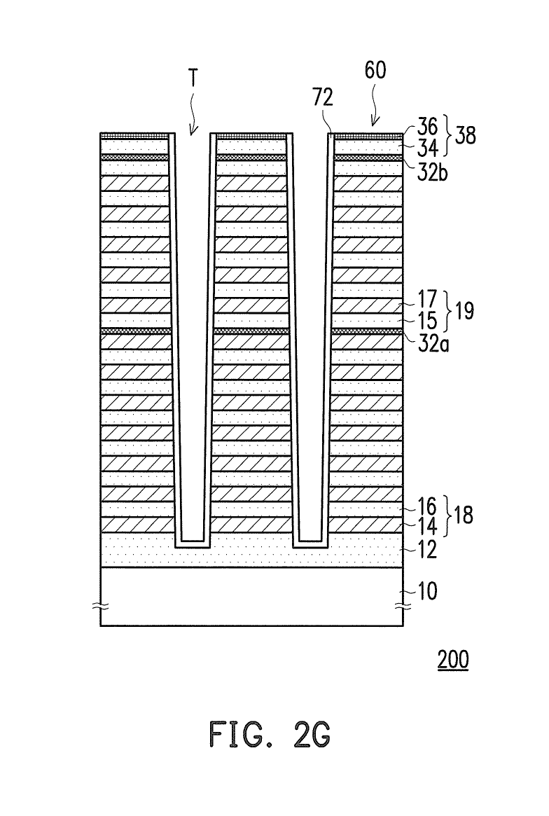

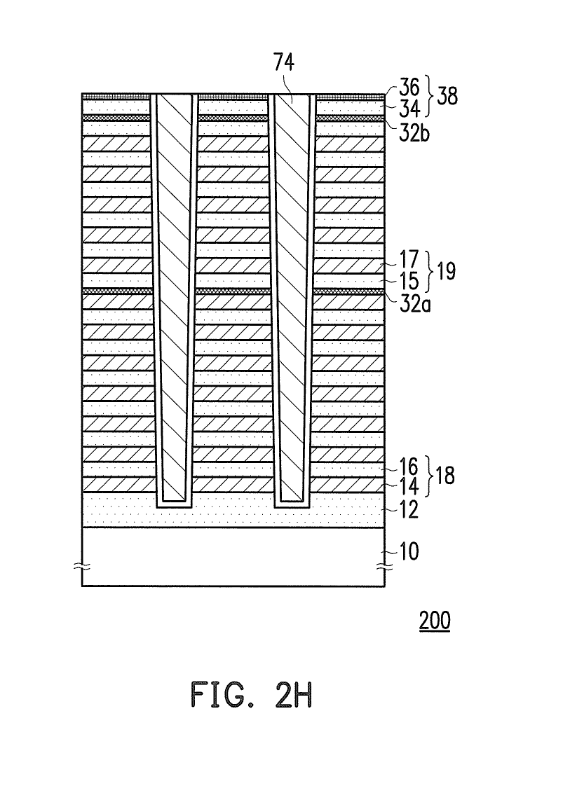

FIG. 2A to FIG. 2H are schematic cross-sectional views illustrating a fabricating method of a semiconductor device according to an embodiment of the invention.

With reference to FIG. 2A and FIG. 2B, the substrate 10 is provided. The material of the substrate 10 has been specified above and thus is not repeated hereinafter. Next, a dielectric layer 22 is formed on the substrate 10. A material of the dielectric layer 22 includes oxide, nitride, nitrogen oxide, or a low dielectric constant material having a dielectric constant smaller than 4. The material of the dielectric layer 22 is silicon oxide, for example. A thickness of the dielectric layer 22 is in a range of 10 nm to 900 nm, for example. A method of forming the dielectric layer 22 includes performing thermal oxidation or chemical vapor deposition, for example.

Next, a plurality of composite layers 28 are formed on the dielectric layer 22. A method of forming the composite layers 28 includes first forming a conductor layer 24 on the dielectric layer 22 and then forming a dielectric layer 26 on the conductor layer 24. However, it should be noted that the invention is not limited thereto. In another embodiment, the method of forming the composite layers 28 includes forming multiple conductor layers 24 and multiple dielectric layers 26 in sequence on the dielectric layer 22.

A material of the conductor layer 24 includes polysilicon or doped polysilicon. A thickness of the conductor layer 24 is in a range of 100 nm to 500 nm, for example. A method of forming the conductor layer 24 includes performing chemical vapor deposition. The dielectric layer 26 includes an oxide layer or a low dielectric constant material having a dielectric constant smaller than 4. A thickness of the dielectric layer 26 is in a range of 100 nm to 500 nm, for example. A method of forming the dielectric layer 26 includes performing thermal oxidation or chemical vapor deposition, for example.

With reference to FIG. 2B, a support layer 42a is formed on a topmost composite layer 28. In an embodiment, a top layer of the topmost composite layer 28 is the conductor layer 24. It should be noted that the topmost conductor layer 24 in FIG. 2B is a seventh conductor layer 24, for example. However, the topmost conductor layer 24 of the invention may be an n^{th} conductor layer 24, wherein n is an integer greater than or equal to 1. Nevertheless, the invention is not limited thereto. In another embodiment, the top layer of the topmost composite layer 28 may be the dielectric layer 26. Likewise, the invention may include forming the support layer 42a on an n^{th} dielectric layer 26.

With reference to FIG. 2C, a plurality of composite layers 29 are formed in sequence on the support layer 42a. The composition, structure, or arrangement of multiple material layers of each composite layer 29 may be the same as or different from the composition, structure, or arrangement of the material layers of each composite layer 28. In an embodiment, when the layer under the support layer 42a is the conductor layer 24, a method of forming the composite layer 29 includes first forming a dielectric layer 30 on the support layer 42a and then forming a conductor layer 31 on the dielectric layer 30. However, it should be noted that the invention is not limited thereto. In another embodiment, when the layer under the support layer 42a is the dielectric layer 26, the method of forming the composite layer 29 includes forming the conductor layers 31 and the dielectric layers 30 in sequence on the support layer 42a. Thereafter, a support layer 42b is formed on the composite layer 29. A material of the support layers 42a and 42b includes silicon carbide, silicon nitride, or a combination thereof, for example. The thickness of the support layers 42a and 42b is in a range of 5 nm to 100 nm, for example. A method of forming the support layers 42a and 42b includes performing chemical vapor deposition or metal organic chemical vapor deposition (MOCVD).

It is worth mentioning that six dielectric layers 30 and five conductor layers 31 that are alternately arranged are disposed between the support layer 42a and the support layer 42b in FIG. 2C, for example. However, this is merely an example. In an embodiment of the invention, m dielectric layers 30 and m−1 conductor layers 31 that are alternately arranged are disposed between the support layer 42a and the support layer 42b, or in dielectric layers 30 and m+1 conductor layers 31 that are alternately arranged are disposed between the support layer 42a and the support layer 42b, for example. In another embodiment, other composite layers 29 are further disposed on the support layer 42b, or other support layers may be formed. The formation of the support layers 42a and 42b in FIG. 2C is merely an example. It should be noted that the number of the support layers of the invention is not limited to the illustrated example.

With reference to FIG. 2D, a hard mask layer 48 is formed on the support layer 42b. The hard mask layer 48 may be a single layer or include multiple layers. In an embodiment, the hard mask layer 48 includes a first hard mask layer 44 and a second hard mask layer 46. The first hard mask layer 44 includes an oxide layer, and a material thereof is silicon oxide or other suitable materials, for example. A thickness of the first hard mask layer 44 is in a range of 10 nm to 200 nm, for example. A method of forming the first hard mask layer 44 includes performing thermal oxidation or chemical vapor deposition. The second hard mask layer 46 includes a nitride layer, and a material thereof is silicon nitride or other suitable materials, for example. A thickness of the second hard mask layer 46 is in a range of 10 nm to 200 nm, for example. A method of forming the second hard mask layer 46 includes performing chemical vapor deposition.

With reference to FIG. 2E, an amorphous carbon layer (ACL) 52, a dielectric anti-reflective coating film (DARC) 54, a bottom anti-reflective coating film (BARC) 56, and a patterned photoresist layer 58 are formed in sequence on the hard mask layer 48.

With reference to FIG. 2E and FIG. 2F, a plurality of stack structures 60 on the substrate and a plurality of trenches T between the stack structures 60 are formed 10 by performing an etching process with the patterned photoresist layer 58 as a mask. The etching process performed on a semiconductor device 200 includes etching the bottom anti-reflective coating film 56, the dielectric anti-reflective coating film 54, the amorphous carbon layer 52, and the hard mask layer 48 with the patterned photoresist layer 58 as the mask, so as to transfer a pattern of the patterned photoresist layer 58 to the hard mask layer 48. The etching process includes anisotropic etching, such as dry etching, for example. The dry etching may be sputter etching, reactive ion etching, etc. Next, the amorphous carbon layer 52, the dielectric anti-reflective coating film 54, the bottom anti-reflective coating film 56, and the patterned photoresist layer 58 that have been etched are removed. Then, the plurality of stack structures 60 and the plurality of trenches T are formed by performing an etching process on the support layer 42b, the dielectric layers 26, the conductor layers 24, the support layer 42a, and the dielectric layer 22 with the patterned hard mask layer 48 as a mask.

With reference to FIG. 2F, each of the stack structures 60 includes the partially patterned dielectric layer 12, a plurality of conductor layers 14, a plurality of dielectric layers 16, the support layers 32a and 32b, and the hard mask layer 38. In an embodiment, each of the stack structures 60 may include only the support layer 32a or include the support layers 32a and 32b, or more support layers. Locations of the support layers 32a and 32b are not restricted to the disclosure of FIG. 2F. In other words, the support layers 32a and 32b may be disposed between any conductor layer 14 and any dielectric layer 16. The trench T is formed between adjacent two stack structures 60. In an embodiment, the width of the trench T is in a range of 5 nm to 30 nm, the depth of the trench T is in a range of 500 nm to 5,000 nm, and the aspect ratio of the trench T is in a range of 10-180, for example.

The fabricating method of the semiconductor device 100 of FIG. 1 is described above for example, but should not be construed as limited to the aforementioned steps. For example, after forming the structure shown in FIG. 2F, other components may be formed as required, which are illustrated by steps of FIG. 2G to FIG. 2H below. Nevertheless, the invention is not limited thereto.

With reference to FIG. 2G, in an embodiment, a charge storage layer 72 may be formed on the patterned dielectric layer 12 and sidewalls of the stack structures 60. The charge storage layer 72 may be a single layer or a multi-layer composite layer. A material of the charge storage layer 72 includes silicon nitride and silicon oxide. In an embodiment, the charge storage layer 72 is a composite layer of an oxide layer/a nitride layer, for example. In another embodiment, the charge storage layer 72 is a composite layer of an oxide layer/a nitride layer/an oxide layer, for example. A method of forming the charge storage layer 72 includes forming a charge storage material layer on the substrate 10 by chemical vapor deposition or thermal oxidation, and then forming the charge storage layer 72 by a lithography and etching process, for example.

With reference to FIG. 2H, a plurality of conductive columns 74 are formed in the trenches T respectively. A material of the conductive column 74 includes polysilicon, N+ doped polysilicon, P+ doped polysilicon, a metal material, or a combination thereof, for example. A method of forming the conductive column 74 includes forming a conductive material layer on the substrate 10 and then polishing the conductive material layer to be substantially even with the second hard mask layer 36 by chemical mechanical polishing, so as to form the conductive columns 74.

It should be noted that, when the semiconductor device 200 is programmed or erased, a direction of the programming and erasing is parallel to a growth direction of the conductor layer 14. That is, electrons or holes enter or exit in a direction from the charge storage layer 72 to the conductor layer 14 (e.g. polysilicon layer). Therefore, even if an electron/hole mobility of the support layers 32a and 32b in the stack structure 60 is lower than an electron/hole mobility of the conductor layer 14 (e.g. polysilicon layer), entry or exit of electrons/holes into or from the conductor layer 14 (e.g. polysilicon layer) is not affected. In other words, the support layer 32a does not affect the original programming and erasing performance of the semiconductor device 200.

To sum up, the invention prevents the stack structures from bending or collapse by forming the support layers in the stack structures of the semiconductor device. Particularly, for the semiconductor device that has high aspect ratio trenches between the stack structures, the overall Young's modulus of the semiconductor device is improved when the support layers having greater Young's modulus than the conductor layers are disposed in the stack structures, such that the stack structures do not deform easily, thereby preventing occurrence of bending or collapse. In addition, when the support layers have a greater band gap than the conductor layers, Z-axis interference between adjacent conductor layers is reduced. Further, the support layers do not affect the original programming and erasing operations of the semiconductor device. In other words, the invention not only improves the overall anti-collapse property of the semiconductor device and reduces Z-axis interference but also maintains the original programming and erasing performance of the semiconductor device.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

1. A semiconductor device, comprising:
a substrate;
a plurality of stack structures disposed on the substrate, wherein a trench is formed between adjacent two stack structures, and each of the stack structures comprises:
a plurality of conductor layers; and
a plurality of dielectric layers disposed alternately with the conductor layers; and
a plurality of support layers disposed in the stack structures respectively,
wherein the support layers are respectively disposed on an upper surface or a lower surface of one of the conductor layers.

2. The semiconductor device according to claim 1, wherein a Young's modulus of the support layers is greater than a Young's modulus of the conductor layers.

3. The semiconductor device according to claim 1, wherein a band gap of the support layers is greater than a band gap of the conductor layers.

4. The semiconductor device according to claim 1, wherein a material of the support layers comprises silicon carbide, silicon nitride, or a combination thereof.

5. The semiconductor device according to claim 1, wherein each of the stack structures comprises two or more of the support layers.

6. (canceled)

7. The semiconductor device according to claim 1, wherein an aspect ratio of the trench is in a range of 10-180.

8. The semiconductor device according to claim 1, further comprising a plurality of conductive columns disposed in the trenches respectively.

9. The semiconductor device according to claim 8, further comprising a charge storage layer disposed between the stack structures and the conductive columns.

10. A semiconductor device, comprising:
a substrate;
a plurality of stack structures disposed on the substrate, wherein a trench is formed between adjacent two stack structures, and each of the stack structures comprises a plurality of composite layers; and
a plurality of support layers respectively disposed above or under the composite layers,
wherein a top surface of the substrate is not exposed by the trench.

11. The semiconductor device according to claim 10, wherein each of the composite layers comprises a conductor layer and a dielectric layer.

12. The semiconductor device according to claim 11, wherein a Young's modulus of the support layers is greater than a Young's modulus of the conductor layers.

13. The semiconductor device according to claim 11, wherein a band gap of the support layers is greater than a band gap of the conductor layers.

14. The semiconductor device according to claim 10, wherein a material of the support layers comprises silicon carbide, silicon nitride, or a combination thereof.

15. The semiconductor device according to claim 10, wherein an aspect ratio of the trench is in a range of 10-180.

16. A semiconductor device, comprising:
a substrate;
a plurality of first stack structures disposed on the substrate, wherein a trench is formed between adjacent two first stack structures;
a plurality of second stack structures disposed on the first stack structures respectively; and
a plurality of support layers disposed between the first stack structures and the second stack structures respectively,
wherein a top surface of the substrate is not exposed by the trench.

17. The semiconductor device according to claim 16, wherein a Young's modulus of the support layers is greater than a Young's modulus of a first conductor layer in the first stack structures and greater than a Young's modulus of a second conductor layer in the second stack structures.

18. The semiconductor device according to claim 16, wherein each of the first stack structures comprises a plurality of first composite layers and each of the second stack structures comprises a plurality of second composite layers, wherein a plurality of material layers of the first composite layers and a plurality of material layers of the second composite layers have different compositions, structures, or arrangements.

19. The semiconductor device according to claim 16, wherein a material of the support layers comprises silicon carbide, silicon nitride, or a combination thereof.

20. The semiconductor device according to claim 16, wherein an aspect ratio of the trench is in a range of 10-180.
